(19) United States
(12) Patent Application Publication
(10) Pub. No.: US 2024/0291467 A1
(43) Pub. Date: Aug. 29, 2024

(54) RESONATOR-BASED FILTER

(71) Applicant: TEXAS INSTRUMENTS INCORPORATED, Dallas, TX (US)

(72) Inventors: YAO YU, SAN JOSE, CA (US); TING-TA YEN, SAN JOSE, CA (US)

(21) Appl. No.: 18/175,132

(22) Filed: Feb. 27, 2023

(51) Int. Cl. H03H 9/60; H03H 9/54; H03H 9/64

(52) U.S. Cl. CPC H03H 9/605; H03H 9/542; H03H 9/6483

(57) ABSTRACT

An integrated circuit (IC) includes a filter circuit having a first input/output (I/O) filter terminal, a second I/O filter terminal, and a reference terminal. The filter circuit includes first and second resonators and first and second inductors. The first resonator has first and second resonator terminals. The first resonator terminal is electrically coupled to the first I/O filter terminal. The second resonator terminal is electrically coupled to the second I/O filter terminal. The second resonator has third and fourth resonator terminals. The third resonator terminal is electrically coupled to the first I/O filter terminal. The first inductor is electrically coupled between the second resonator terminal and the reference terminal. The second inductor is electrically coupled between the fourth resonator terminal and the reference terminal. The second inductor is magnetically coupled to the first inductor.

### RELATED APPLICATION

The present application is related to U.S. patent application Ser. No. 18/145,497, titled “Integrated Balun and Filter”, filed on Dec. 22, 2022, which is hereby incorporated herein by reference in its entirety.

### BACKGROUND

A filter can perform a filtering operation on an input signal to produce a filtered version of the input signal. One type of filter is a bandpass filter. A bandpass filter can pass a portion of the input signal in a passband frequency relatively unattenuated and attenuates another portion of the input signal outside the passband frequency. It is desirable for the bandpass filter to have a reduced footprint, especially if the bandpass filter is integrated with other circuit components in an integrated circuit (IC).

### SUMMARY

In an example, an integrated circuit (IC) includes a filter circuit having a first input/output (I/O) filter terminal, a second I/O filter terminal, and a reference terminal. The filter circuit includes first and second resonators and first and second inductors. The first resonator has first and second resonator terminals. The first resonator terminal is electrically coupled to the first I/O filter terminal. The second resonator terminal is electrically coupled to the second I/O filter terminal. The second resonator has third and fourth resonator terminals. The third resonator terminal is electrically coupled to the first I/O filter terminal. The first inductor is electrically coupled between the second resonator terminal and the reference terminal. The second inductor is electrically coupled between the fourth resonator terminal and the reference terminal. The second inductor is magnetically coupled to the first inductor.

### BRIEF DESCRIPTION OF THE DRAWINGS

FIG. 1 is a schematic illustrating a cross-sectional view of an example semiconductor device including a filter.

FIG. 2 and FIG. 3 are schematic illustrating example systems including the example device of FIG. 1.

FIG. 4 is a schematic illustrating an example bandpass filter including resonators.

FIG. 5A includes a schematic illustrating an example resonator and a graph illustrating an example frequency response of the resonator.

FIG. 5B is a graph illustrating an example frequency response of the bandpass filter of FIG. 4,

FIG. 6 is a schematic illustrating an example internal component of the bandpass filter of FIG. 4.

FIG. 7 is a schematic illustrating a perspective view of the example internal component of FIG. 6.

FIG. 8 is a schematic illustrating an example internal component of the bandpass filter of FIG. 4.

FIG. 9 is a schematic illustrating a cross-sectional view of the example internal component of FIG. 8.

FIG. 10, FIG. 11, and FIG. 12 are schematics illustrating various views of the example internal component of FIG. 9.

FIG. 13 include schematics illustrating the example internal component of FIG. 8.

### DETAILED DESCRIPTION

The same reference numbers or other reference designators are used in the drawings to designate the same or similar (either by function and/or structure) features.

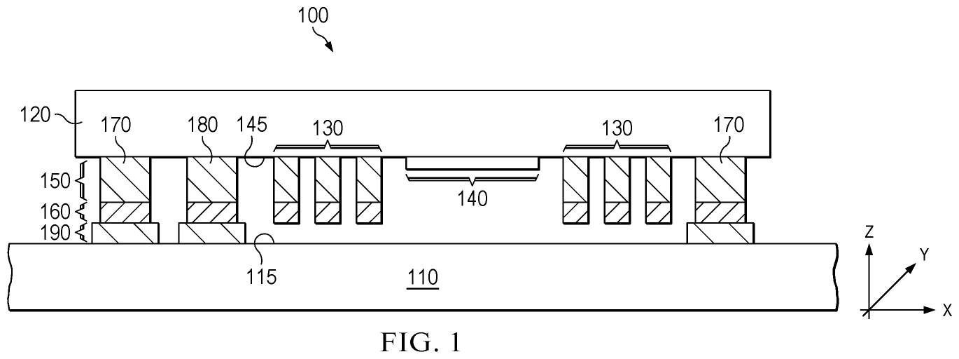

FIG. 1 illustrates a cross-sectional view of an example semiconductor device 100 including a filter. Device 100 includes two semiconductor dies 110 and 120 coupled together, each having a respective stack of patterned and etched layers thereon.

Semiconductor die 110 includes certain circuitry and other features, such as driver or control circuitry (not explicitly shown) configured to provide electrical signals to circuitry on semiconductor die 120. Semiconductor die 110 can also receive electrical signals from circuitry on semiconductor die 120. A conductive layer 190 on die 110 has conductive pads, which facilitate coupling between semiconductor dies 110 and 120. Certain conductive pads of conductive layer 190 may facilitate creating an electrical interconnection between an output terminal of driver or control circuitry on die 110 and circuitry on die 120.

Semiconductor die 120 includes certain circuitry and other features, including a processing circuit 130, a filter 140 coupled to the processing circuit 130, a conductive layer 150 including interconnects (e.g., posts) 170 and 180, and a solder layer 160. Filter 140 can include one or more resonators, such as bulk acoustic wave (BAW) resonators, on die 120. As to be described below, processing circuit 130 can perform conversion between a single-ended signal and differential signals. Processing circuit 130 can receive a single-ended input signal and convert to differential input signals, and provide the differential input signals to the filter 140. Processing circuit 130 can also receive differential output signals from the filter 140, and convert to a single-ended output signal.

In the example shown in FIG. 1, die 110 and 120 are coupled together in a flip-chip arrangement, in which die 120 is inverted or flipped relative to an orientation used to form a layered stack of material thereon (e.g., layers 150 and 160). Other examples may use wire bonding to form electrical interconnections between circuitry on die 110 and circuitry on die 120. In the flip-chip arrangement shown in FIG. 1, die 120 has a surface 145 facing a surface 115 of die 110. Die 110 and 120 are interconnected through posts 170 and 180 to form a cavity around certain circuitry on die 110 or 120.

A description of an example process for coupling dies together in a flip-chip arrangement is provided in U.S. Pat. No. 7,790,509, assigned to Texas Instruments Inc., which is incorporated herein in its entirety. An example description of bump structures which facilitate a flip-chip coupling of two die together, one die having a BAW resonator and the other die having corresponding oscillator driver circuit, is provided in U.S. Pat. No. 10,574,184, assigned to Texas Instruments Inc., which is incorporated herein in its entirety.

A conductive layer 150 having certain patterned features extends from surface 145 of die 120. The patterned features of conductive layer 150 include interconnects/posts 170 and 180 and at least a portion of the processing circuit 130. A solder layer 160 is over conductive layer 150. Solder layer 160 forms a barrier that surrounds at least filter 140, protecting it from mechanical stress and from contamination. In some examples, solder layer 160 is a continuous structure. In some examples, solder layer 160 has segmented portions. Solder layer 160 may be used, for example, in a solder reflow process to form solder joints connecting posts 170 and 180 on die 120 to corresponding conductive pads 190 of die 110.

In the illustrated example, posts 170 extending from die 120 are soldered together with corresponding conductive pads 190 on die 110, thereby forming a continuous sealing barrier that encompasses circuitry on die 120, including at least respective portions of the processing circuit 130 and filter 140. The sealing barrier may form a sealed cavity around certain stress-sensitive circuitry formed on die 120.

Post 180 provides a conductive input/output (I/O) interconnect between driver or control circuitry on die 110 and corresponding circuitry on die 120, such as respective portions of the processing circuit 130 or filter 140. Post 180 thus enables the formation of a circuit including respective circuitry on both die 110 and 120. In some examples, in addition to or in lieu of providing an I/O interconnect, post 180 forms a continuous sealing barrier that encompasses inward-facing circuitry on die 120, such as respective portions of processing circuit 130 or filter 140. Where post 180 provides a sealing barrier, post 170 may be omitted altogether or, alternatively, conductive layer 150 may include multiple posts 170 at separate locations to enhance the structural integrity of the physical interconnection between die 110 and die 120.

The flip-chip arrangement shown in FIG. 1 facilitates packaging stress-sensitive circuitry, such processing circuit 130 or filter 140 on die 120, together with related semiconductor die 110. Stress-sensitive circuitry has electrical characteristics that can be adversely affected by mechanical stress. Examples include precision reference circuits, diodes, filters, sensors, resonators, and so forth. Unwanted stress on stress-sensitive circuitry may be reduced or eliminated, for example, by coupling together a first semiconductor die 110 having driver or control circuitry thereon to a second semiconductor die 120 having stress-sensitive circuitry thereon (e.g., processing circuit 130 or filter 140).

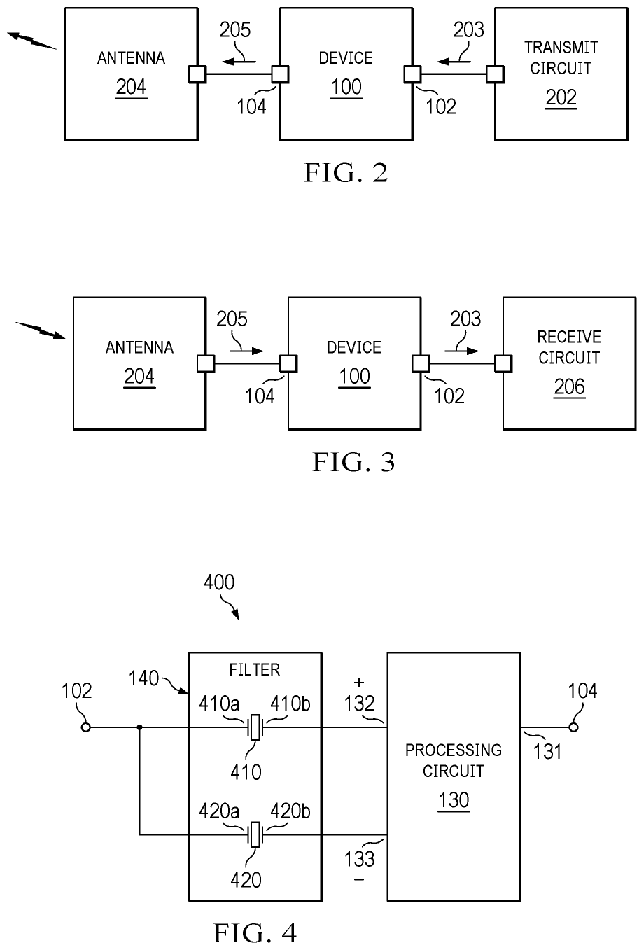

FIGS. 2 and 3 illustrate example systems including semiconductor device 100. The semiconductor device 100 includes input input/output (I/O) filter terminals 102 and 104. In FIG. 2, a transmit circuit 202 is coupled to I/O filter terminal 102, and an antenna 204 is coupled to I/O filter terminal 104. The transmit circuit 202 can generate a signal 203, which it provides to I/O filter terminal 102 of device 100. Device 100 filters the signal 203 (e.g., bandpass filters the signal 203) and produces a filtered output signal 205 at its I/O filter terminal 104. The filtered output signal 205 can be provided to the antenna 204 for wireless transmission therefrom. In FIG. 3, the antenna 204 may wirelessly receive a signal, which the antenna converts to an electrical signal 205. The electrical signal 205 is provided to I/O filter terminal 104 of device 100. Semiconductor device 100 filters (e.g., bandpass filters) the signal 205 and provides a filtered output signal 203 at I/O filter terminal 102 to receive circuit 206.

FIG. 4 is a schematic illustrating a bandpass filter 400 including the filter 140 coupled to the processing circuit 130. In some examples, filter 140 includes a first resonator 410 and a second resonator 420. Although two resonators are shown in this implementation, more than two resonators can be included in other implementations. For example, one or more resonators may be coupled in parallel with resonator 410, and one or more resonators may be coupled in parallel with resonator 420. Resonator 410 includes resonator terminals 410a and 410b. Resonator 420 includes resonator terminals 420a and 420b. Input/output filter terminal 102 of device 100 is coupled to resonator terminal 410a of resonator 410 and to resonator terminal 420a of resonator 420. The processing circuit has a single-ended terminal 131, a positive terminal 132, and a negative terminal 133, where positive terminal 132 and negative terminal 133 can form a pair of differential terminals. Resonator terminal 410b of resonator 410 is coupled to the positive terminal 132 of the processing circuit 130, and resonator 420b of resonator 420 is coupled to the negative terminal 133. Input/output filter terminal 104 of device 100 is coupled to terminal 131 of the processing circuit 130. As described above, device 100 can receive a signal at either of its I/O filter terminals 102 or 104, filter the received signal, and output a filtered signal at the other I/O filter terminal. The resonators 410, 420 may be any type of micro-acoustic resonator, electromagnetic resonator, lumped-element resonator, etc. In one example, each resonator 410 and 420 is a bulk acoustic wave (BAW) resonator. In another example, the resonators 410, 420 are surface acoustic wave (SAW) resonators.

In the example of a BAW resonator, the resonator (e.g., resonators 410 and 420) may include thin film layer of a piezoelectric material sandwiched between two conductive (e.g., metal) electrodes. These layers are formed on an acoustic mirror which includes alternating layers of high and low acoustic impedance materials (e.g., a Bragg Stack). The acoustic mirror also may be implemented through air gaps on top and bottom of the metal electrodes. Electrical signals are coupled into the piezoelectric layer via the electrodes and due to the piezoelectricity, the piezoelectric layer changes dimensions (e.g., thickness). The longitudinal acoustic wave created is resonant in the layered structure and as such the frequency of operation can be controlled by the layer thickness and acoustic properties of the layers. The large currents that result at the acoustic resonance produce impedance changes that allow such resonators to be used as a filter.

As described above, processing circuit 130 can perform conversion between a single-ended signal and differential signals. Specifically, in a case where the filter 140 receives an input voltage signal at filter I/O terminal 102, each of resonators 410 and 420 can generate a current responsive to the input voltage signal, and the processing circuit 130 can provide an output signal at the filter I/O terminal 104 representing a difference between the currents. Also, in a case where the filter 140 receives an input voltage signal at filter I/O terminal 104, the processing circuit 130 can provide a differential voltage signals across the resonators 410 and 420, and the currents provided by the resonators 410 and 420 can combine at the filter I/O terminal 102.

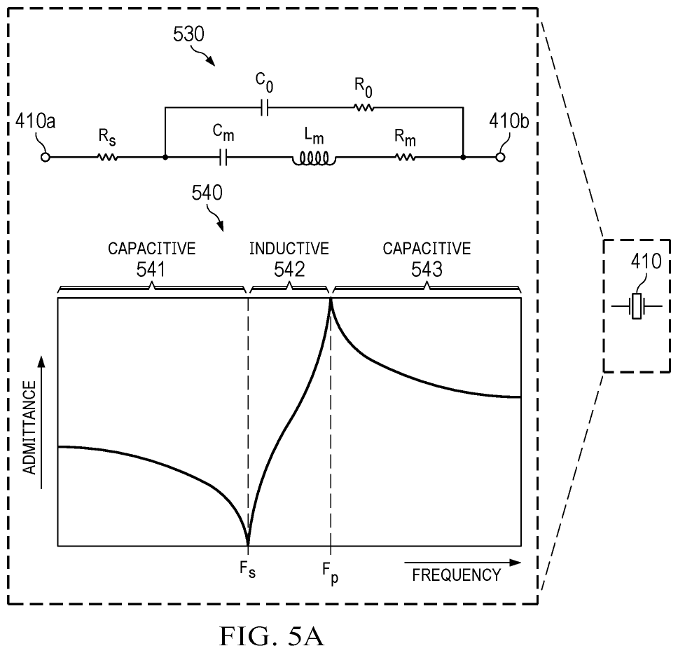

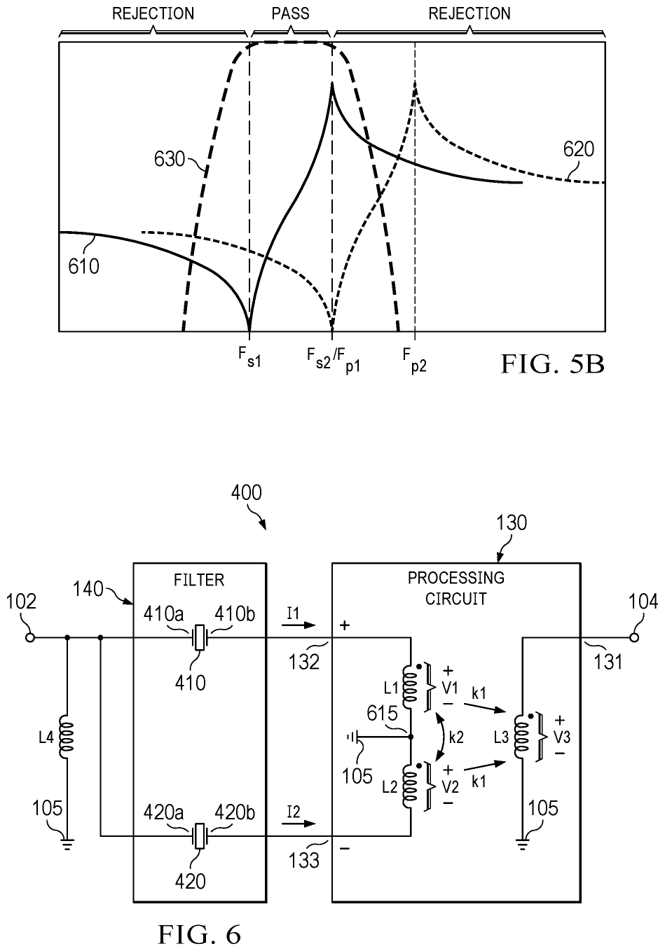

The resonators 410 and 420 and the processing circuit 130 can form bandpass filter 400. Specifically, as to be illustrated below in FIGS. 5A and 5B, responsive to a voltage signal within a passband frequency range of the bandpass filter 400, the current signals provided by the resonators 410 and 420 can have a phase difference of 180 degrees, and the current signals can add to each other in the output signal at the filter I/O terminal 104, so that the output signal can represent the unattenuated voltage signal. Also, responsive to a voltage signal outside the passband frequency range of the bandpass filter 400, the current signals provided by the resonators 410 and 420 can have the same phase, and the current signals can cancel each other in the output signal the filter I/O terminal 104, so that the output signal can be zero or represent a substantially attenuated version of the voltage signal. The resonators 410 and 420 can also provide an output signal at the filter I/O terminal 102 representing the non-attenuated differential voltage signals if the voltage signals are within the passband frequency range. Resonators 410 and 420 can also provide an output signal representing zero volts, or an output signal representing a substantially attenuated version of the differential voltage signals at the filter I/O terminal 102 if the voltage signals are outside the passband frequency range. Using resonators to provide bandpass filtering can provide improved selectivity, such as sharp roll off and narrow passband.

FIG. 5A includes a schematic of an electrical model 530 of each BAW resonator 410, 420 and a graph 540 representing an example variation of admittance of the resonator with frequency of the model. The model 530 includes a series resonant path and a parallel resonant loop between the resonator terminals 410a and 410b. The series resonant path includes a piezoelectric capacitor Cₘ, a piezoelectric inductor Lₘ, and a resistor Rₘ. Piezoelectric capacitor Cₘ is motional capacitance, which is inversely proportional to the stiffness of the piezoelectric layer. Piezoelectric inductor Lₘ is motional inductance which represents the mass of the piezoelectric film. Resistor Rₘ is the motional resistance which represents the damping of the piezoelectric film's vibration. The parallel resonant loop includes a parasitic parallel plate capacitor C₀, resistor R₀ (which is the parasitic resistance of the parasitic parallel plate capacitor C₀), resistor Rₘ, the piezoelectric inductor Lₘ, and the piezoelectric capacitor Cₘ. Resistor Rₛ is coupled between terminal 410 and capacitors Cₘ and C₀, and represents resistance of metal routing, electrodes, etc.

The graph 540 for the resonator shows a series resonant frequency Fₛ and a parallel resonant frequency Fₚ. The series resonant path defines a path in which the impedance of the resonator quickly decreases to a small minimum resonance value (Rₘ) at the resonant frequency Fₛ at which the piezoelectric capacitor Cₘ and the piezoelectric inductor Lₘ cancel. At frequency Fₛ, a low impedance path across the resonator is created. At frequencies significantly lower than the series resonant frequency Fₛ (region 541 in FIG. 5A), the impedance of piezoelectric inductor Lₘ is nearly a short, and thus the impedance of the resonator is dominated by the parallel combination of capacitors Cₘ and C₀. At such frequencies, the resonator has a capacitive impedance and, to a first approximation, can be modeled as a capacitor between resonator terminals 410a and 410b. At frequencies significantly higher than the parallel resonance frequency Fₚ (in frequency region 543 in FIG. 5A), the impedance of inductor Lₘ increases significantly resulting in the impedance of the resonator being dominated by the parasitic parallel plate capacitor C₀, and the resonator's impedance thus is also largely capacitive at such frequencies. For frequencies at the parallel resonance (Fₚ), current travels around the loop instead of being transmitted from terminal 410a, through the resonator, and out terminal 410b, and so the resonator becomes an open circuit and has a high impedance at the parallel resonance frequency Fₚ. Also, between the series resonant frequency Fₛ and the parallel resonant frequency Fₚ, the resonator's impedance is dominated by inductor Lₘ, and the impedance of the resonator is inductive.

The resonator can provide a current signal responsive to a voltage signal across the resonator and according to the impedance of the resonator. Accordingly, for a frequency between the series resonant frequency Fₛ and the parallel resonant frequency Fₚ, the resonator's impedance is inductive, and the current signal lags the voltage signal by 90 degrees. Also, for frequencies either lower than the series resonant frequency Fₛ or above the parallel resonant frequency Fₚ, the resonator's impedance is capacitive, and the current signal leads the voltage signal by 90 degrees.

The resonators 410 and 420 are tuned to have different series resonant frequencies (Fₛ) and different parallel resonant frequencies (Fₚ). Together with processing circuit 130, resonators 410 and 420 can form bandpass filter 400. FIG. 5B illustrates graphs 610, 620, and 630 that illustrate the properties of resonators 410 and 420 to provide bandpass filtering. Graph 610 represents an example variation of admittance with respect to frequency for resonator 410, and graph 620 represents an example variation of admittance with respect to frequency for resonator 420. Referring to graphs 610 and 620, the series resonant frequency Fₛ₁ for resonator 410 is below the series resonant frequency Fₛ₂ for resonator 420. Also, the parallel resonant frequency Fₚ₁ for resonator 410 is below the parallel resonant frequency Fₚ₂ for resonator 420.

The resonators 410 and 420 combine to implement the bandpass filter 400 having a frequency response 630, in which the bandpass filter 400 has a bandpass frequency range between the series resonant frequencies Fₛ₁ and Fₛ₂. In a case where both resonators 410 and 420 receive a voltage signal at filter I/O terminal 102, if the voltage signal has a frequency outside the bandpass frequency range (e.g., being lower than Fₛ₁ or higher than Fₛ₂), both resonators 410 and 420 can provide capacitive impedance, and each of the current signals provided by both resonators leads the voltage signal by 90 degrees. Processing circuit 130 provides the output signal at filter I/O terminal 104 based on a difference between the current signals provided by resonators 410 and 420. Accordingly, the current signals can cancel or at least attenuate each other, and the output signal can represent zero volts or an attenuated version of the voltage signal.

Also, if the voltage signal has a frequency inside the bandpass frequency range (e.g., between Fₛ₁ and Fₛ₂), resonator 410 can have an inductive impedance and provide a current signal that lags the voltage signal by 90 degrees, while resonator 420 can have a capacitive impedance and provide a current signal that leads the voltage signal by 90 degrees, and the current signals are 180 degrees out of phase. Because the processing circuit 130 provides the output signal based on a difference between the current signals, the out of phase current signals can add to (or reinforce) each other in the output signal. Accordingly, the output signal represents an unattenuated version of the voltage signal.

Also, in a case where the processing circuit 130 provides 180 degrees out of phase voltage signals to resonators 410 and 420, if the voltage signals are outside the bandpass frequency range, both resonators 410 and 420 can provide capacitive impedance, and each provides a current signal that leads the respective voltage signal by 90 degrees. Accordingly, the current signals provided by resonators 410 and 420 can retain the 180 degree phase difference and cancel out/attenuate each other at filter I/O terminal 102, and the output signal at filter I/O terminal 102 can be zero or represent an attenuated version of the voltage signals. On the other hand, if the voltage signals are within the bandpass frequency range, resonator 410 can have an inductive impedance and provide a current signal that lags the voltage signal by 90 degrees, while resonator 420 can have a capacitive impedance and provide a current signal that leads the voltage signal by 90 degrees. Accordingly, the current signals provided by the resonators 410 and 420 can be in phase and can add to/reinforce each other at filter I/O terminal 102, and the output signal at filter I/O terminal 102 can represent the unattenuated version of the voltage signals.

FIG. 6 is a schematic of an example of the bandpass filter 400 in the semiconductor device 100. Referring to FIG. 6, the processing circuit 130 includes inductors L1, L2, and L3. Inductors L1, L2, and L3 form a balun to combine the differential outputs from resonators 410 and 420 to produce a single-ended output at the I/O filter terminal 104. Inductor L1 is electrically coupled in series with inductor L2 between resonator terminal 410b of resonator 410 (at the processing circuit's positive terminal 132) and resonator terminal 420b of resonator 420 (at the processing circuit's negative terminal 133). The connection point 615 between inductors L1 and L2 is coupled to a reference terminal 105 (e.g., a ground terminal). Accordingly, inductor L1 is electrically coupled between resonator terminal 410b and the reference terminal, and inductor L2 is electrically coupled between resonator terminal 420b and the reference terminal. Inductor L3 is electrically coupled between the processing circuit's terminal 131 and the reference terminal 105. The processing circuit's terminal 131 is electrically coupled to the I/O filter terminal 104.

Inductor L3 is magnetically coupled to each of inductors L1 and L2 and is not electrically coupled to either inductor L1 or L2. The magnetic coupling coefficient between two inductors indicates the degree to which the magnetic flux generated by a current in one inductor can induce a current in the other inductor. The magnetic coupling coefficient is designated by the letter “k” and ranges from 0 to 1. If the entire magnetic flux of one inductor is coupled to the other inductor, the magnetic coupling coefficient k is 1 (perfect coupling). In practice, the coupling coefficient k between two inductors is less than 1.

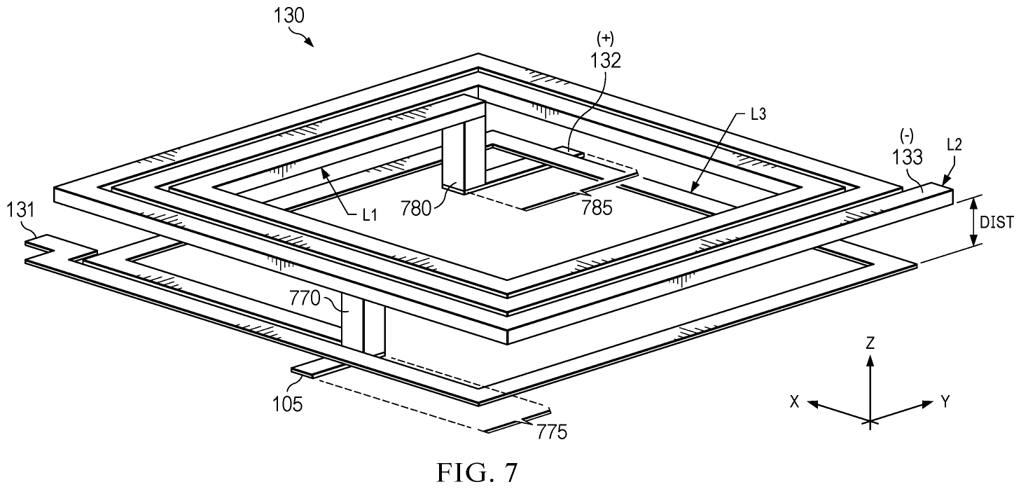

In the example processing circuit 130 of FIG. 6, the coupling coefficient k1 between inductor L1 and L3 and between inductors L2 and L3 is close to 1, while the coupling coefficient k2 between inductors L1 and L2 is substantially smaller than 1. The coupling coefficients k1 and k2 are dictated, at least in part, by how the inductors L1, L2, and L3 are formed on device 100. FIG. 7 (described below) provides an example as to how inductors L1, L2, and L3 can be formed. The coupling coefficient k2 is also kept low to reduce the parasitic mutual capacitance between L1 and L2.

As described above, at frequencies outside the passband frequency range of the bandpass filter 400, both resonators of filter 140 are capacitive in nature and thus attenuate the signal provided at the I/O filter terminals 102 or 104. Within the passband of filter 140, one resonator (e.g., resonator 410) is capacitive, and the other resonator (e.g., resonator 420) is inductive. With one resonator representing a capacitive impedance, the current from that resonator leads its voltage by 90 degrees, and the current from the other resonator lags its voltage by 90 degrees. For example, assuming resonator 410a is capacitive within the passband and resonator 420b is inductive within the passband, current I1 from resonator 410 leads the voltage across resonator 410 by 90 degrees, and current I2 from resonator 420 lags the voltage across resonator 420 by 90 degrees. Accordingly, the phase difference between the resonators' currents I1 and I2 is 180 degrees.

The balun in the processing circuit 130 converts the differential signal from the resonators 410 and 420, which is provided to the positive and negative terminal 133s of the processing circuit 130, to a single-ended signal on the processing circuit's terminal 131, which is coupled to the I/O filter terminal 104. The conversion can be based on the magnetic coupling between L1 and L3 and between L2 and L3. The single-ended signal at the I/O filter terminal 104 is referenced with respect to the reference terminal 105.

Inductors L1, L2, and L3 are fabricated in such a way to provide the polarity shown in FIG. 6. The “dot” for inductor L1 is at its upper terminal at the positive terminal 132 of the processing circuit 130. The dot for inductor L2 is at its upper terminal at the reference terminal. The dot for inductor L3 is at its upper terminal at I/O filter terminal 104. Accordingly, the voltage signal across V3 inductor L3 is in phase with the voltage signal V1 between the positive terminal 132 and the connection point 615/reference terminal 105 as current flows into inductor L1 from resonator 410. Similarly, the voltage V3 across inductor L3 is also in phase with the voltage signal V2 between the connection point 615/reference terminal 105 and the negative terminal 133 as current flows into inductor L2 from resonator 420. If the current signals from the resonators 410 and 420 are 180 degree out of phase (e.g., because the input signal at I/O filter terminal 102 is within the passband), and with connection point 615 forced to 0V due to connection to the ground terminal, the voltage signal V2 is also in phase with the voltage signal V1. Accordingly, through equal magnetic couplings between L1 and L3 and between L2 and L3 (having a coefficient of k1), the voltage signal V3 across inductor L3 can be an equally-weighted sum of voltage signals V1 and V2, and the voltage signal V3 can represent the unattenuated version of the input signal at I/O filter terminal 102. On the other hand, if the current signals from the resonators 410 and 420 are in phase (e.g., because the input signal is outside the passband), the voltage signal V2 is out of phase with the voltage signal V1, and the voltage V3 across inductor L3 can be a difference between voltage signals V1 and V2 and represent the attenuated version of the input signal.

Also, in a case where filter I/O terminal 104 receives an input signal, through magnetic couplings between L1 and L3 and between L2 and L3, processing circuit 130 can provide voltage signals V1 and V2 as differential (and 180 degrees out of phase) signals. As described above, if the input signal is within the passband, resonators 410 and 420 can generate in phase current signals that add/reinforce each other at the filter I/O terminal 102 to represent an unattenuated version of the input signal. Also, if the input signal is outside the passband, resonators 410 and 420 can generate out of phase current signals that cancel/attenuate each other at the filter I/O terminal 102 to represent an attenuated version of the input signal.

In some examples, the bandpass filter 400 may include an inductor L4 coupled between I/O filter terminal 102 and the reference terminal 105 (e.g., a ground terminal). Inductor L4 can resonate with the parasitic parallel plate capacitors C₀ of the resonators 410 and 420 to cancel (or attenuate) the impact of the parallel plate capacitors on the overall impedance of the filter 140. The capacitance of the parasitic parallel plate capacitor C₀ can act as a current bypass and degrade the performance of the filter. In some examples where C₀ is small, inductor L4 may be omitted. FIG. 7 is a schematic illustrating a perspective view of the example balun of the processing circuit 130 of FIG. 6. In the example of FIG. 7, balun 130 has a stacked arrangement of inductors L1 and L2 at least partially superimposed over inductor L3 (e.g., along the illustrated z-axis). Inductors L1 and L2 are both magnetically coupled to secondary inductor L3 along the illustrated z-axis.

In the example of FIG. 7, inductors L1, L2, and L3 can be in the form of coil windings or can be in the form of quarter wavelength transmission lines. Each of inductors L1 and L2 is a patterned and etched portion of conductive layer 150. Inductor L1 has a conductive path extending between the positive terminal 132 and the reference terminal 105. Inductor L2 has a conductive path extending between the negative terminal 133 and the reference terminal 105. Inductor L3 is a patterned and etched portion of a conductive layer and has a conductive path extending from the reference terminal 105 to the processing circuit's terminal 131.

A first via 770 is electrically coupled between inductors L1 and L2 and is further electrically coupled to reference terminal 105. Via 770 may be formed, for example, by fabrication processes including a deposition, a selective pattern and an etch of conductive layer 150. A conductive path 775 between a base of via 770 and reference terminal 105 is formed in a conductive layer in a direction parallel to the y-axis. A portion of inductor L3 extending parallel to the illustrated x-axis is routed over or under conductive path 775.

A second via 780 is coupled between inductor L1 and the positive terminal 132. Via 780 may be formed, for example, by fabrication processes including a deposition, a selective pattern and an etch of conductive layer 150. Conductive path 785 between via 780 and the positive terminal 132 is formed in a conductive layer in a direction parallel to the illustrated y-axis. A portion of inductor L3 extending parallel to the illustrated x-axis is routed over or under conductive path 785.

FIG. 7 illustrates that inductors L1 and L2 are formed in the same metal layer, which is a different metal layer in which inductor L3 is formed. A dielectric layer (not shown) is between the metal layers in which inductors L1/L2 and L3 are formed. By stacking L3 with each of L1 and L2, and having L1 and L2 formed in the same metal layer, the separation between L1 and L3 and between L2 and L3 can be substantially the same (representing by distance DIST), which allows the magnetic couplings between L1 and L3 and between L2 and L3 to be substantially equal (e.g., k1). Placing inductors L1 and L2 on the same metal layer can result in a lower level of magnetic coupling k2 between L1 and L2 compared to the magnetic coupling k1 between L1 and L3 and between L2 and L3 and a lower level of the parasitic mutual capacitance between L1 and L2. Specifically, the separation between L1 and L2 can be several times more than the separation between the separation between L1 and L3 and between L2 and L3 (DIST). This can be due to patterning precision and semiconductor design rules which may impose an upper limit on the distance between adjacent metal traces in a metal layer. On the other hand, adjacent metal layers in a stack may be separated only by the relatively thin dielectric layer between such layers. The increased separation between L1 and L2 compared with between L1 and L3 and between L2 and L3 can lead to a smaller k2 than k1. Further, having L1 and L2 on the same metal layer may increase the footprint of the processing circuit 130 due to the increased separation between L1 and L2.

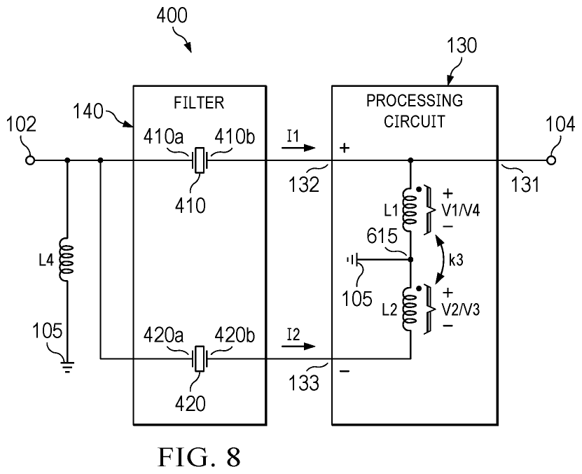

FIG. 8 shows an example semiconductor device 100 having a processing circuit 130 with reduced footprint. In FIG. 8, the processing circuit 130 includes inductors L1 and L2. The I/O filter terminal 104 for the device 100 of FIG. 8 is electrically coupled to resonator terminal 410b and inductor L1 and thus to the positive terminal 132 of the processing circuit 130. In some examples (not shown in the figures), the I/O filter terminal 104 can be electrically coupled to resonator terminal 420b and inductor L2 and thus to the negative terminal 133 of the processing circuit 130.

Referring still to FIG. 8, inductor L1 is electrically coupled between resonator terminal 410b and reference terminal 105. Inductor L2 is electrically coupled between resonator terminal 420b and reference terminal 105. The connection 615 between inductors L1 and L2 is coupled to the reference terminal 105 (e.g., a ground terminal). Inductors L1 and L2 in FIG. 8 are formed in such a way that the magnetic coupling coefficient k3 between the inductors is substantially higher than the corresponding magnetic coupling coefficient k1 between the corresponding inductors in FIG. 6. In one example, k3 is 0.8 or higher. In some examples, k3 can be 0.8, 0.9, or 0.95. In some examples, k3 can be 0.9 or higher. That k3 is larger than k2 may result from inductors L1 and L2 in FIG. 8 being formed in an interleaved, stacked arrangement across two adjacent metal layers separated only the relatively thin dielectric layer between the metal layers, whereas inductors L1 and L2 in FIG. 6 are formed on the same metal layer (which limits the proximity of adjacent traces as described above). Accordingly, inductors L1 and L2 of FIG. 8 are closer together than the corresponding inductors L1 and L2 of the balun example of FIG. 6.

In FIG. 8, with a magnetic coupling coefficient close to 1 and given the relative polarities of the inductors as indicated by the dots, inductors L1 and L2 can generate the output signal at filter I/O terminal 104 by combining the currents I1 and I2 from resonators 410 and 420 (in a case where filter I/O terminal 102 receives an input signal). Inductors L1 and L2 can also provide a differential voltage signal at the positive and negative terminal 133s of the processing circuit 130 to resonators 410 and 420, which allow the resonators to provide an output signal at filter I/O terminal 102 based on a combination of the resonator currents.

Specifically, as current I1 flows through inductor L1, a voltage signal V1 is generated across inductor L1 between the positive terminal 132 of the processing circuit 130, and a magnetic field is generated in inductor L1. Through magnetic coupling having a magnetic coupling coefficient close to 1, and the symmetricity of L1 and L2 over reference terminal 105, the magnetic field can induce a voltage signal V2 across inductor L2 having the same amplitude as V1 and between the reference terminal 105 and the negative terminal 133 of the processing circuit 130. With the reference terminal 105 being a ground terminal and forced to 0V, V2 can be a 180 degree out of phase version of V1. Also, as current I2 flows through inductor L2, a voltage signal V3 is generated across inductor L2 between the reference terminal 105 and the negative terminal 133 of the processing circuit 130, and a magnetic field is generated in inductor L2. Through magnetic coupling having a magnetic coupling coefficient close to 1 and the symmetricity between L1 and L2 over reference terminal 105, the magnetic field can also induce a voltage signal V4 across inductor L1 having the same amplitude as V2 and between the positive terminal 132 of the processing circuit 130 and the reference terminal 105, and the voltage signal V4 can be a 180 degree out of phase version of V3.

If the input signal at the filter I/O terminal 102 is within the passband frequency range, the currents I1 and I2 can be 180 degrees out of phase. Voltage signals V1 and V4 can be in phase and reinforce each other, and voltage signals V2 and V3 can be in phase and reinforce each other. The output signal at the filter I/O terminal 104 can represent an unattenuated version of the input signal. On the other hand, if the input signals filter I/O terminal 102 is outside the passband frequency range, the currents I1 and I2 can be in phase. Voltage signals V1 and V4 can be out of phase and cancel/attenuate each other, and voltage signals V2 and V3 can be out of phase and cancel/attenuate each other. Accordingly, the output signal at the filter I/O terminal 104 can be zero or represent an attenuated version of the input signal.

On the other hand, if filter I/O terminal 102 receives an input signal (e.g., a current signal), the current signal flows through inductors L1, which generates the V1 voltage signal and a magnetic field. The magnetic field also induces the V2 voltage signal having the same amplitude as the V1 voltage signal between the reference terminal 105 and the negative terminal 133 of the processing circuit 130, and the V1 and V2 voltage signals can be 180 degree out of phase. Accordingly, the processing circuit 130 can provide differential voltage signals at the positive and negative terminal 133s to the respective resonators 410 and 420. If the differential voltage signals are within the passband frequency range, the current signals provided by the resonators can be in phase and add to each other at the filter I/O terminal 102, and the output signal at the filter I/O terminal 102 can represent the unattenuated version of the input signal at the filter I/O terminal 104. But if the differential voltage signals are outside the passband frequency range, the current signals provided by the resonators can be out of phase and cancel/attenuate each other, and the output signal at the filter I/O terminal 102 can represent zero or an attenuated version of the input signal at the filter I/O terminal 104.

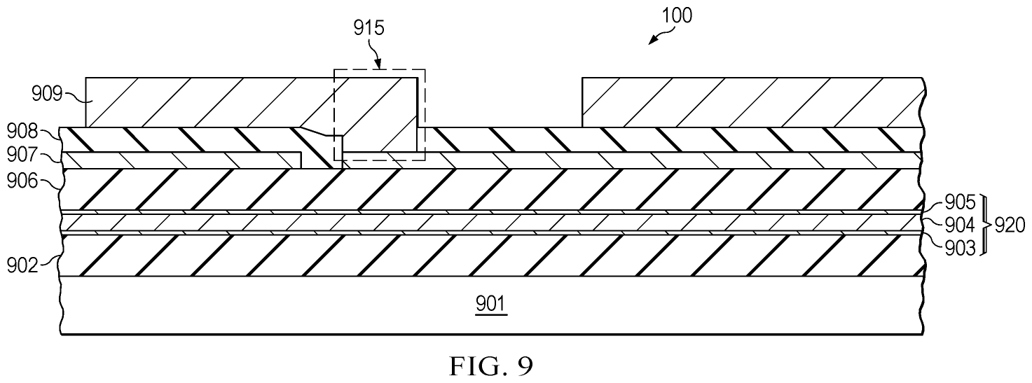

FIG. 9 is a cross-sectional view of a portion of an example device 100 which includes layers 901-909 and may include additional conductive and insulative layers. Layer 901 is silicon. Layers 902 and 906 are a dielectric material such as an oxide (e.g., silicon dioxide). Layers 903, 904, and 905 form the acoustic mirror 920. Layers 903 and 905 may be a conductive material (e.g., molybdenum, which is commonly called “moly”), and layer 904 may be aluminum nitride.

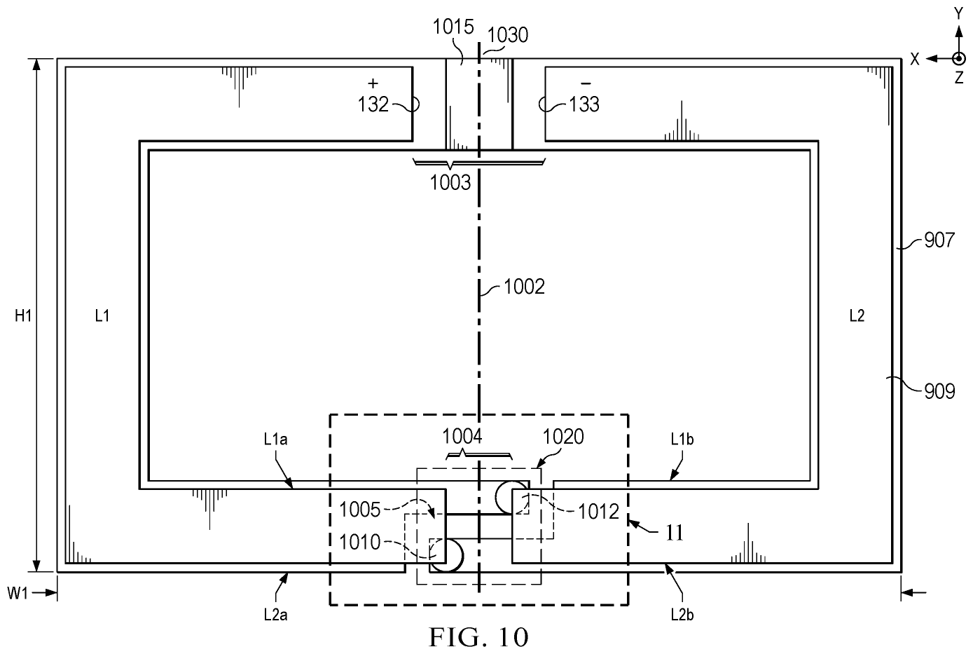

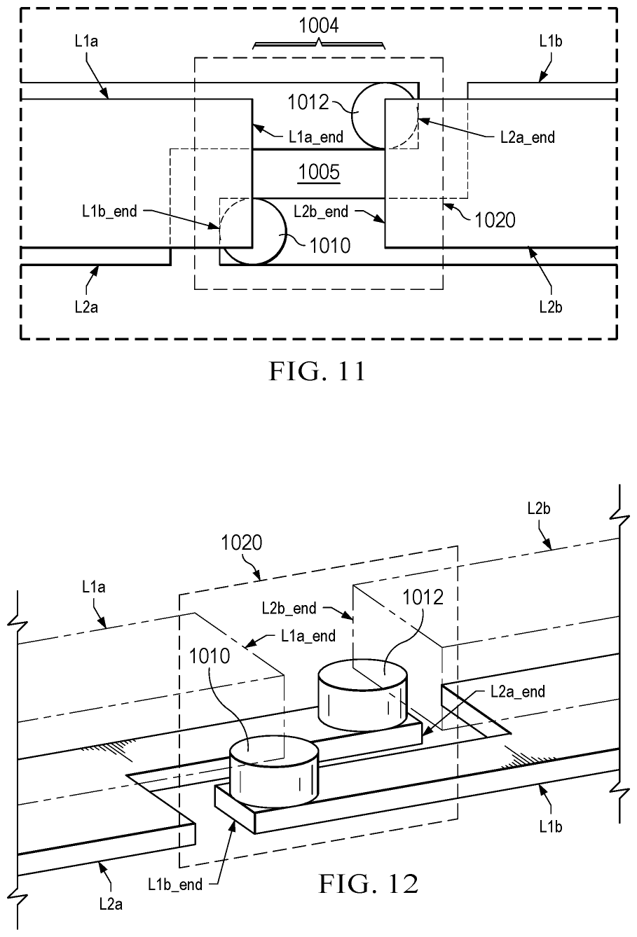

Layers 907 and 909 are metal layers in which inductors L1 and L2 are formed. Layer 907 be aluminum, and layer 909 may be copper. Metal layers 907 and 909 may be made from different types of metal material or from the same type of metal material (e.g., both aluminum or both copper). Metals other than aluminum and/or copper may be used to form layers 907 and 909. Metal layers 907 and 909 are electrically separated from each other by an insulating layer 908 such as a dielectric material (e.g., silicon nitride). A portion 915 of layer 909 is thicker than other portions of layer 909. The thicker portion 915 implements a via to interconnect layers 909 and 907 to thereby help form inductors L1 and L2 in an interleaved, vertically-stacked arrangement, as described below regarding FIGS. 10-12.

FIG. 10 is a top-down view of the processing circuit 130 of FIG. 8 illustrating the interleaved, vertically-stacked arrangement of inductors L1 and L2. With this arrangement of the inductors, the magnetic coupling coefficient of the inductors is sufficiently large to cause the processing circuit 130 to convert the differential output from resonators 410 and 420 at the positive and negative terminal 133 of the processing circuit to a single-ended output signal at the processing circuit's terminal 130.

FIG. 10 shows the two metal layers 909 and 907 with layer 909 separated from layer 907 by insulating layer 908 (layer 908 is not shown in FIG. 10). Each inductor L1 and L2 includes at least one segment of the inductor in each metal layer 907 and 909. Inductor L1 includes segment L1a in layer 909 and segment L1b in layer 907. Inductor L2 includes segment L2a in layer 907 and segment L2b in layer 909. The segments L1a and L1b in separate layers 909 and 907 are electrically coupled together by way of a via 1010 in region 1020. Similarly, segments L2a and L2b in separate layers 909 and 907 are electrically coupled together by way of a via 1012.

A voltage signal V1 between the positive terminal 132 and the ground causes a current signal to flow from the positive terminal 132 counterclockwise through L1a, via 1010, L1b, and reach the contact pad 1015 (representing connection point 615 to the ground terminal). This generates a magnetic field that points out of the paper (e.g., along the z axis). The magnetic field can induce a voltage signal V2 between the contact pad 1015 and the negative terminal 133. Because the magnetic coupling factor between L1 and L2 being close to one, and the contact pad 1015 has a zero voltage (or a reference voltage), V1 and V2 can have the same amplitude but 180 degrees out of phase. Also, the flow of I1 and I2 current signals (illustrated in FIG. 8) can also induce voltage signals across L1 and L2 that may add up or cancel each other depending on the phase relationships of the current signals (which depend on the frequency of the current signals) as they flow through the inductors L1 and L2 of FIG. 9, as explained above.

FIG. 11 is a close-up perspective view of region 1020 which includes vias 1010 and 1012 interconnecting metal layers 907 and 909. Referring to FIGS. 10 and 11, starting at the positive terminal 132 of inductor L1, inductor segment L1a extends counterclockwise approximately halfway around the loop in which the inductors are formed to and end L1a_end in region 1020. Via 1010 electrically connects end L1a_end of inductor segment L1a in metal layer 909 to end L1b_end of inductor segment L1b in metal layer 907. From there, inductor segment L1b continues in layer 907 counterclockwise around the loop to contact pad 1115. Contact pad 1015 can represent the connection point 615 between the inductors L1 and L2 shown in FIG. 8. The contact pad 1015 may be coupled to the reference terminal 105, as described above.

One end of inductor segment L2a of inductor L2 is at the contact pad 1015 and extends counterclockwise around the loop underneath inductor segment L1a of inductor L1 to region 1020. Via 1012 couples the end L2a_end of inductor segment L2a to the end L2b_end of inductor segment L2b of inductor L2. Inductor segment L2b in layer 909 extends counterclockwise approximately halfway around the loop over inductor segment L1b and terminates at an end which represents the negative terminal 133, as shown.

Layer 907 includes a separation portion 1005 which electrically isolates inductor segment L2a of inductor L2 from inductor segment L1b of inductor L1. Layer 909 includes a separation portion which electrically isolates inductor segment L1a of inductor L1 from inductor segment L2b of inductor L2. Layer 909 also has a separation portion 1003 which electrically isolates the end of inductor segment L1a representing the positive terminal 132 from the end of inductor segment L2b which represents the negative terminal 133.

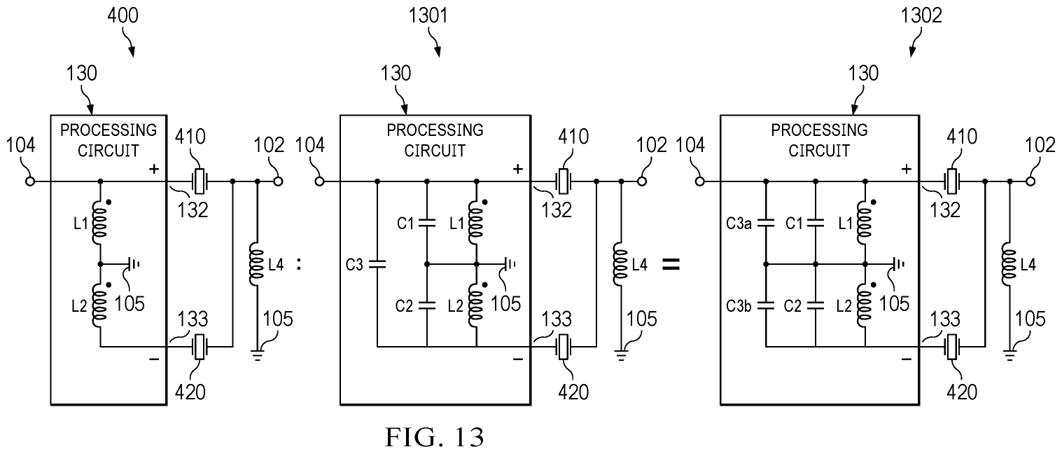

As is shown in FIG. 10, each segment of inductor L1 at least partially overlaps a segment of inductor L2. Segments L1a (of inductor L1) and L2a (of inductor L2) at least partially overlap each other. Similarly segments L2b (of inductor L2) and L1b (of inductor L1) at least partially overlap each other. In some examples, the overlapping segments of inductors L1 and L2 fully overlap each other to increase the magnetic coupling coefficient between inductors L1 and L2. The outer width of inductors L1 and L2 is W1, and the outer height of the inductors is H1. The dimensions W1 and H1 are further described below regarding FIG. 13.

FIG. 12 is a diagram of region 1020 which illustrates that the vias 1010 and 1020 are formed as thickened regions of the respective metal layers 909 and 907. One of these thickened regions is illustrated in FIG. 9 as thickened region 915.

As described above, the inductors L1 and L2 are implemented in a vertically-stacked arrangement between two parallel metal layers to increase magnetic coupling between L1 and L2. Such arrangements also increase the parasitic mutual capacitances between L1 and L2. However, because the inductors L1 and L2 are used to combine/reinforce out of phase voltage/current signals through magnetic coupling, the parasitic mutual capacitances can be in parallel with the inductances represented by the inductors L1 and L2, and can increase the effective inductance of the inductors L1 and L2. This allows the reduction of the inductances of L1 and L2 to achieve a particular impedance, which in turn can reduce the width W1 and height L1 of the inductors L1 and L2, and the overall footprint of the inductors L1 and L2 and of the processing circuit 300.

FIG. 13 includes schematics of equivalent circuit models 1301 and 1302 of processing circuit 130 of FIG. 8 including the parasitic mutual capacitances between L1 and L2. In equivalent circuit model 1301, parasitic capacitances C1, C2, and C3 represent the parasitic capacitances between the positive, negative, and reference terminals. Parasitic capacitance C1 represents the parasitic capacitance between the positive terminal 132 and the reference terminal 105. Parasitic capacitance C2 represents the parasitic capacitance between the negative terminal 133 and the reference terminal 105. Parasitic capacitance C3 represents the parasitic capacitance between the positive terminal 132 and the negative terminal 133.

In equivalent circuit model 1302, parasitic capacitance C3 can be represented by a parasitic capacitance C3a coupled between the positive terminal 132 and the reference terminal 105, and a parasitic capacitance C3b coupled between the reference terminal 105 and the negative terminal 133. This can be due to the 180 degree phase difference in the signals at the positive terminal 132 and the negative terminal 133 caused by the high coefficient of magnetic coupling between inductors L1 and L2, effectively creating a virtual ground at the middle of C3.

Parasitic capacitance C3a is in parallel with parasitic capacitance C1 and with inductor L1, and the parallel combination of C3a, C1, and L1 has a higher effective impedance and inductance than L1 alone. Also, parasitic capacitance C3b is in parallel with parasitic capacitance C2 and with inductor L2, and the parallel combination of C3b, C2, and L2 has a higher effective impedance and inductance than L2 alone. Accordingly, the inductances of L1 and L2 can be reduced to achieve a particular inductance/impedance. The width W1 and height L1 of the inductors L1 and L2 can be reduced, and the overall footprint of the inductors L1 and L2 and of the processing circuit 300 can also be reduced. In one example, W1 is 300 micrometers (microns), and H1 is 500 microns, whose area (150,000 square microns) may be smaller than the footprint area occupied by the balun of FIG. 7 including the three inductors L1, L2, and L3.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

What is claimed is:

1. An integrated circuit (IC), comprising:
a filter circuit having a first input/output (I/O) filter terminal, a second I/O filter terminal, and a reference terminal, the filter circuit including:
a first resonator having first and second resonator terminals, the first resonator terminal electrically coupled to the first I/O filter terminal, the second resonator terminal electrically coupled to the second I/O filter terminal;
a second resonator having third and fourth resonator terminals, the third resonator terminal electrically coupled to the first I/O filter terminal;
a first inductor electrically coupled between the second resonator terminal and the reference terminal; and
a second inductor electrically coupled between the fourth resonator terminal and the reference terminal, in which the second inductor is magnetically coupled to the first inductor.

2. The IC of claim 1, wherein the first resonator and the second resonator are configured as a band pass filter.

3. The IC of claim 1, wherein:
the first resonator is configured to provide a first signal at the second resonator terminal responsive to a second signal at the first resonator terminal; and
the second resonator is configured to provide a third signal at the fourth resonator terminal responsive to the second signal at the second resonator terminal, the third signal having a 180-degree phase shift with respect to the first signal.

4. The IC of claim 1, wherein a magnetic coupling coefficient between the first and second inductors is 0.8 or higher.

5. The IC of claim 1, wherein the reference terminal is a ground terminal.

6. The IC of claim 1, wherein the first and second resonators are bulk-acoustic wave (BAW) resonators, surface acoustic wave (SAW) resonators, electromagnetic resonators, or lumped element circuit.

7. The IC of claim 1, wherein:
the first inductor includes a first winding portion and a second winding portion;
the second inductor includes a third winding portion and a fourth winding portion;
the first winding portion forms a first stack with the third winding portion; and
the second winding portion forms a second stack with the fourth winding portion.

8. The IC of claim 7, wherein:
the first winding portion at least partially overlaps the third winding portion; and
the second winding portion at least partially overlaps the fourth winding portion.

9. The IC of claim 7, further comprising:
a semiconductor die including the first and second resonators;
a first metal layer on the semiconductor die; and
a second metal layer on the semiconductor die,
wherein the first winding portion and the fourth winding portion are in the first metal layer, and the second winding portion and the third winding portion are in the second metal layer.

10. The IC of claim 9, further comprising:
an insulation layer between part of the first and second metal layers;
a first via through the insulation layer and electrically coupled between the first and second winding portions; and
a second via through the insulation layer and electrically coupled between the third and fourth winding portions.

11. The IC of claim 9, wherein the first winding and the second winding are symmetrical over the reference terminal; and
wherein the third winding and the fourth winding are symmetrical over the reference terminal.

12. The IC of claim 9, wherein the first metal layer includes aluminum, and the second metal layer includes copper.

13. The IC of claim 9, wherein the semiconductor die is a first semiconductor die having a first surface, the first metal layer is between the second metal layer and the first surface, and the IC further comprises:
a second conductor die having a second surface opposing the first surface; and
metal interconnects electrically coupled between the second metal layer and the second surface.

14. The IC of claim 1, further comprising a third inductor electrically coupled between the first filter terminal and the reference terminal.

15. An integrated circuit (IC), comprising:
a filter circuit having a first input/output (I/O) filter terminal, a second I/O filter terminal, and a reference terminal, the filter circuit including:
a first resonator electrically coupled between the first I/O filter terminal and the second I/O filter terminal;
a second resonator electrically coupled between the first I/O filter terminal and the reference terminal;
a first inductor electrically coupled between the second I/O filter terminal and the reference terminal, the first inductor including a first winding portion and a second winding portion, the first winding portion in a first metal layer and the second winding portion in a second metal layer; and
a second inductor electrically coupled between the second resonator and the reference terminal, the second inductor including a third winding portion and a fourth winding portion, the third winding portion in the second metal layer and the fourth winding portion in the first metal layer.

16. The filter of claim 15, wherein:
the first winding portion is at least partially overlaps the third winding portion; and
the fourth winding portion is at least partially overlaps the second winding portion.

17. The filter of claim 15, wherein a magnetic coupling coefficient between the first and second inductors is 0.8 or higher.

18. The filter of claim 15, wherein the first and resonators are bulk-acoustic wave (BAW) resonators.

19. An integrated circuit (IC), comprising:
a die having a first surface and a second surface opposite the first surface; and
a filter circuit having a first input/output (I/O) filter terminal, a second I/O filter terminal, and a reference terminal, the filter circuit including:
first and second inductors in an interleaved, vertically stacked arrangement between the first and second surfaces;
a first resonator electrically coupled in series with the first inductor between the first I/O filter terminal and the reference terminal, the second I/O filter terminal electrically coupled to the first resonator and to the first inductor; and
a second resonator electrically coupled in series with the second inductor between the first filter terminal and the reference terminal.

20. The IC of claim 19, wherein:
the die has a first metal layer, a second metal layer, and a dielectric layer between the first and second metal layers;
the first inductor includes a first winding portion and a second winding portion, the first winding portion in the first metal layer and the second winding portion in the second metal layer; and
the second inductor including a third winding portion and a fourth winding portion, the third winding portion in the second metal layer and the fourth winding portion in the first metal layer.

21. The IC claim 20, wherein at least a portion of the first winding portion at least partially overlaps at least a portion of the third winding portion, and at least a portion of the second winding portion at least partially overlaps at least a portion of the fourth winding portion.

22. The IC of claim 19, wherein a magnetic coupling coefficient between the first and second inductors is 0.8 or higher.

23. The IC of claim 19, wherein the first and second resonators are bulk-acoustic wave (BAW) resonators.
